(19) United States
(12) Patent Application Publication
(10) Pub. No.: US 2020/0255940 A1
(43) Pub. Date: Aug. 13, 2020

(54) METHOD FOR CLEANING PROCESS CHAMBER

(71) Applicant: Applied Materials, Inc., Santa Clara, CA (US)

(72) Inventors: Byung Seok KWON, San Jose, CA (US); Lu XU, Santa Clara, CA (US); Prashant Kumar KULSHRESHTHA, San Jose, CA (US); Seoyoung LEE, Hwaseong-Si (KR); Dong Hyung LEE, Danville, CA (US); Kwangduk Douglas LEE, Redwood City, CA (US)

(21) Appl. No.: 16/784,456

(22) Filed: Feb. 7, 2020

Related U.S. Application Data
(60) Provisional application No. 62/810,691, filed on Feb. 26, 2019.
(60) Provisional application No. 62/803,898, filed on Feb. 11, 2019.

(51) Int. Cl. C23C 16/44; H01L 21/67; H01J 37/32

(52) U.S. Cl. CPC C23C 16/4405; H01J 37/32862; H01L 21/6719

(57) ABSTRACT

Implementations of the disclosure generally relate to a method of cleaning a semiconductor processing chamber. In one implementation, a method of cleaning a deposition chamber includes flowing a nitrogen containing gas into a processing region within the deposition chamber, striking a plasma in the processing region utilizing a radio frequency power, introducing a cleaning gas into a remote plasma source that is fluidly connected to the deposition chamber, generating reactive species of the cleaning gas in the remote plasma source, introducing the cleaning gas into the deposition chamber, and removing deposits on interior surfaces of the deposition chamber at different etch rates.

### CROSS-REFERENCE TO RELATED APPLICATIONS

This application claims benefit of U.S. Provisional Patent Application Ser. No. 62/803,898, filed Feb. 11, 2019, and Ser. No. 62/810,691, filed Feb. 26, 2019, both of which are hereby incorporated by reference herein.

### BACKGROUND

### Field

Implementations disclosed herein generally relate to a method for cleaning a semiconductor processing chamber.

### Description of the Related Art

In the fabrication of integrated circuits and semiconductor devices, materials are typically deposited on a substrate in a process chamber, such as a deposition chamber, such as a plasma enhanced chemical vapor deposition (PECVD) chamber. The deposition processes typically result in deposition of some of the material on gas distribution showerheads as well as the walls and components of the deposition chamber. The material deposited on the chamber walls and components can affect the deposition rate from substrate to substrate and the uniformity of the deposition on the substrate. Due to this errant deposition, repeatability is often difficult to achieve unless the chamber is cleaned.

Therefore, there is a need for improved methods of cleaning a chamber

### SUMMARY

Implementations of the disclosure generally relate to a method of cleaning a semiconductor processing chamber. In one implementation, a method of cleaning a deposition chamber includes flowing a nitrogen containing gas into a processing region within the deposition chamber, striking a plasma in the processing region utilizing a radio frequency power, introducing a cleaning gas into a remote plasma source that is fluidly connected to the deposition chamber, generating reactive species of the cleaning gas in the remote plasma source, introducing the cleaning gas into the deposition chamber, and removing deposits on interior surfaces of the deposition chamber at different etch rates.

In another implementation, a method of cleaning a deposition chamber includes flowing a nitrogen containing gas into a processing region within the deposition chamber, striking a plasma in the processing region utilizing a radio frequency power, introducing a cleaning gas into a remote plasma source that is fluidly connected to the deposition chamber, generating reactive species of the cleaning gas in the remote plasma source, introducing the cleaning gas into the deposition chamber, and removing deposits on interior surfaces of the deposition chamber at different temperatures.

In another implementation, a method of cleaning a deposition chamber includes flowing a first gas into a processing region within the deposition chamber, striking a plasma of the first gas in the processing region utilizing a radio frequency power, introducing a second gas into a remote plasma source that is fluidly connected to the deposition chamber, generating reactive species of the second gas in the remote plasma source, introducing the second gas into the deposition chamber, and removing deposits on interior surfaces of the deposition chamber at different temperatures and etch rates.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 is a partial cross sectional view of one implementation of a plasma system.

FIG. 2 is a graph comparing cleaning rates at different electrode spacing.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

The present disclosure generally provides methods and apparatus for cleaning deposition chambers, such as deposition chambers used in the fabrication of integrated circuits and semiconductor devices. The deposition chambers that may be cleaned using the methods described herein include chambers that may be used to deposit oxides, such as carbon-doped silicon oxides, and other materials. In one implementation, the plasma chamber is utilized in a plasma enhanced chemical vapor deposition (PECVD) system. Examples of PECVD systems that may be adapted to benefit from the implementations described herein include a PRODUCER® SE CVD system, a PRODUCER® GT™ CVD system or a DXZ® CVD system, all of which are commercially available from Applied Materials, Inc., Santa Clara, Calif. The Producer® SE CVD system (e.g., 200 mm or 300 mm) has two isolated processing regions that may be used to deposit thin films on substrates, such as conductive films, silanes, carbon-doped silicon oxides and other materials. Although the exemplary implementation includes two processing regions, it is contemplated that the implementations described herein may be used to advantage in systems having a single processing region or more than two processing regions. It is also contemplated that the implementations described herein may be utilized to advantage in other plasma chambers, including etch chambers, ion implantation chambers, plasma treatment chambers, and stripping chambers, among others. It is further contemplated that the implementations described herein may be utilized to advantage in plasma processing chambers available from other manufacturers.

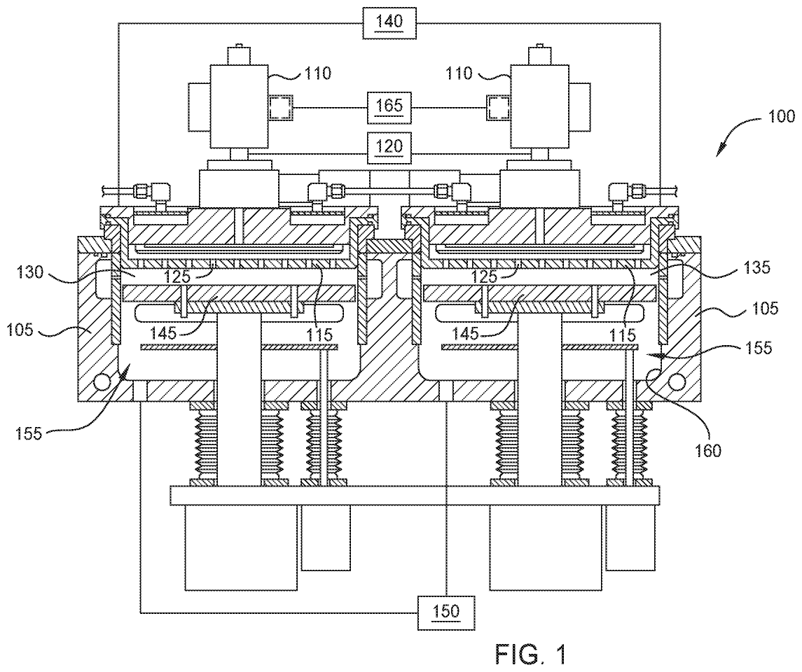

An example of a chamber that may be used to advantage is shown in FIG. 1. FIG. 1 shows a cross sectional view of a twin chamber system 100 having two discrete processing chambers 105. Each of the processing chambers 105 is connected to a remote plasma source 110. The remote plasma sources 110 generate a reactive species of cleaning gases that is flowed to the interior of the processing chambers 105. Each of the processing chambers 105 also has a showerhead or a perforated faceplate 115. Each of the processing chambers 105 are coupled to a gas source 120. Each perforated faceplate 115 includes openings 125 formed therethrough for delivering process gases, or precursors, or a cleaning gas, from the gas source 120 to respective processing regions 130 and 135 in each of the processing chambers 105.

While the remote plasma sources 110 are shown coupled to a top of the processing chambers 105, the reactive species generated therein may flow to the processing chambers 105 through the top of the processing chambers 105, a side of the processing chambers 105, or another location.

Each of the perforated faceplates 115 are coupled to a power source 140. The power source 140 is configured to produce a plasma between the perforated faceplate 115 and a heated pedestal 145 in each of the processing regions 130 and 135. The heated pedestal 145 is also configured to electrostatically chuck a substrate (not shown). The power source 140 may be a direct current power source or an alternating current power source, such as a radio frequency (RF) power source. The plasma is utilized to dissociate gases from the gas source 120, such as process gases and cleaning gases.

Each of the processing regions 130 and 135 are coupled to a pump 150. The pump 150 is a vacuum pump that is utilized to remove unused gases and/or by-products from the processing chambers 105. The pump 150 includes a valve, such as a throttle valve (not shown) that is utilized to control pressure in the processing chambers 105.

In operation, process gases or precursors are supplied to the processing regions 130 and 135 from the gas source 120. The process gases or precursors flow through the openings 125 in the perforated faceplates 115. A plasma of the process gases or precursors is formed in each of the processing regions 130 and 135 by the power source 140. The plasma forms films on, or etches films from, a substrate (not shown) that is supported by the heated pedestal 145 in each of the processing regions 130 and 135.

After a number of cycles of film formation on, or etching of, substrates in each of the processing chambers 105, the interior of the processing chambers 105 is cleaned. Chamber cleaning processes (aka a “stripping” process) improves film deposition in semiconductor manufacturing. Chamber cleaning processes control the health of the chamber and on-substrate process stability. As semiconductor devices utilize higher memory density, and therefore thicker multi-stack structures (i.e. 3D VNAND, 3D ReRAM, DRAM, NAND, logic and foundry), the capability of completely cleaning the chamber within the shortest amount of time increases the throughput. Within current cleaning processes, as film thickness is scaled to meet high aspect ratio requirements, the cleaning time will likewise increase. For instance, as the thickness of hard-masks are increased two-fold, the process time is expected to be one half of the prior generation devices to meet same throughput per production tool per hour.

Chemical vapor deposition (CVD) using carbon hardmasks at temperatures greater than about 400 degrees Celsius is one of the most prevalent hardmask processes for semiconductor device fabrication. This is due to the masks high etch selectivity and chemical simplicity for cleaning processes. Due to a relatively high etch selectivity and easiness to deposit, up to about 10 micron (μm), carbon films are used as the hardmask. However, as next generation devices utilize even thicker multi-stack structures, there is a need for increasing the throughput. For example, carbon based hardmasks (single component or multi components of C, Si, N, O, F).

As processing of semiconductor devices advances, it is contemplated that clean rate of the chamber may result in a bottle neck for overall production. Further, under-cleaning the chamber can cause accumulated residues in the chamber over time and further damage hardware components or limit the capability to refurbish those hardware components.

Conventionally, an RF cleaning is utilized at high temperatures (greater than about 400 degrees Celsius). A remote plasma (RPS) cleaning process using fluorine based chemistry is not a viable option due to formation of AlFₓ particles, even though RPS cleaning has a slightly higher etch rate as compared to RF cleaning processes. Furthermore, current argon (Ar) and oxygen (O₂) based RF cleaning chemistry is not capable of removing the aluminum oxycarbide (AlOₓ) formed at the openings 125 in the perforated faceplate 115. Additionally, RF cleaning using O₂ containing chemistry provides numerous challenges, one of which is insufficient chamber bottom cleaning due to relatively unstable plasma at higher spacing (e.g., the size of the processing regions 130 and 135 between the heated pedestal 145 and the perforated faceplate 115).

Further, AlOₓ formation on the openings 125 of the perforated faceplate 115 changes the emissivity of the perforated faceplate 115. The emissivity change causes process drift over time and/or impacts substrate to substrate repeatability.

According to the embodiments disclosed herein, a multi-source plasma cleaning method is provided. The multi-source plasma cleaning method as described herein increases throughput dramatically while efficiently cleaning chamber components as compared to conventional cleaning methods.

Through testing it is found that a fluorine based RPS cleaning provides a cleaning efficiency that is superior to solely an RF cleaning process (e.g., an in-situ generated plasma) in general. However, high power RF cleaning processes provide a similar or even greater cleaning efficiency as compare to RPS cleaning at certain regions of the chamber. The multi-source plasma cleaning method as disclosed herein combines the RF cleaning with the RPS cleaning with superior results.

For example, an RF cleaning process, applied in the processing regions 130 and 135 using the power source 140 (between the perforated faceplate 115 and the heated pedestal 145), using a nitrogen/oxygen (N₂/O₂) mixture is provided herein. The N₂/O₂ mixture is about 1˜50% N₂ to about 99˜50% O₂. The N₂/O₂ mixture is provided at a flow rate of about 5 L to about 25 L (slm). Pressure in the chamber is about 2 Torr to about 15 Torr. RF power is about 1000 W to about 5000 W, which provides a temperature in the processing regions 130 and 135 of greater than about 400 degrees Celsius.

An RPS cleaning process, in conjunction with the RF cleaning process described above, is provided herein. The RPS cleaning process, using the remote plasma sources 110, cleans a lower portion of the processing chambers 105. For example, sidewalls 160 of the processing chambers 105 are cleaned with the RPS cleaning process using a nitrogen trifluoride/oxygen (NF₃/O₂) mixture. The sidewalls 160 are typically much cooler than components of the processing chambers 105 adjacent to the processing regions 130 and 135. For example, while the temperature of the processing regions 130 and 135 is at or greater than about 400 degrees Celsius, the sidewalls 160 are at least 100 degrees Celsius cooler. The NF₃/O₂ mixture is provided by a cleaning gas source 165 coupled to the processing chambers 105. The NF₃/O₂ mixture is energized into a plasma in the remote plasma sources 110 and provided to the processing chambers 105 in this energized state. The NF₃/O₂ mixture is about 1˜50% NF₃ to about 99˜50% O₂. The NF₃/O₂ mixture is provided at a flow rate of about 5 L to about 25 L (slm). Pressure in the chamber is about 2 Torr to about 15 Torr. The RPS cleaning process may be provided simultaneously with the RF cleaning process, or the RPS cleaning process is provided shortly after the RF cleaning process. For example, the RPS cleaning process is performed after the chamber has been evacuated and purged after the RF cleaning process.

The RF cleaning process is utilized to clean the openings 125 of the perforated faceplate 115 as well as other portions of the processing chambers 105 adjacent to the processing regions 130 and 135. The RF cleaning process is very fast and efficient, and removes localized AlOₓ formations in or on the perforated faceplate 115. For example, openings 125 of the perforated faceplate 115 are cone shaped which introduces a low pressure zone adjacent to the openings 125. Conventional argon based deposition processes introduce a micro-arcing in this low pressure region. Carbon films on the aluminum oxide perforated faceplate 115 convert to aluminum oxycarbide. This aluminum oxycarbide is extremely difficult or even non-removable by Ar/O₂ RF cleaning chemistries. However, using the N₂/O₂ cleaning chemistry, the aluminum oxycarbide is removed completely. Then a brief RPS cleaning will clean the rest of the chamber with very high cleaning efficiency. Furthermore, use of N₂/O₂ with the RF cleaning provides an excellent solution to residue formed at openings 125 of the perforated faceplate 115 due to microarcing described above. The N₂/O₂ RF cleaning provides an effective control mechanism for process drift due to emissivity changes overtime and also a control mechanism for substrate sliding/electrostatic chucking stability of a substrate on the heated pedestal 145.

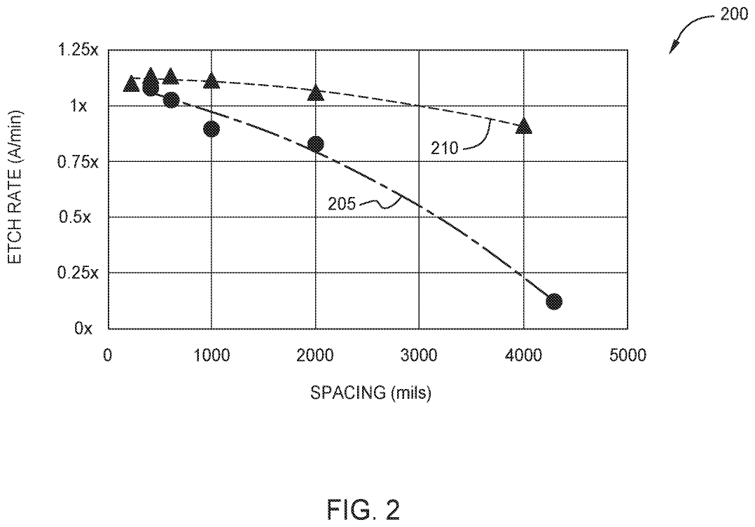

FIG. 2 is a graph 200 showing the difference in cleaning rate at different electrode spacing (the distance between the perforated faceplate 115 and the heated pedestal 145). The curve 205 shows the performance of the N₂/O₂ RF cleaning method as described herein. The N₂/O₂ RF cleaning method is compared to the NF₃/O₂ RPS cleaning method as described herein (shown by curve 210). The RF cleaning has a cleaning (etch) rate that is comparable to RPS cleaning (etch) rate at the top of the chamber (near the processing regions 130 and 135). However, as the spacing is increased, the N₂/O₂ cleaning rate decreases dramatically.

In contrast, the NF₃/O₂ RPS cleaning method does not decrease as dramatically, even at a bottom of the chamber. The cleaning rate of the NF₃/O₂ RPS at bottom of the chamber is about six-fold greater as compared to the cleaning rate of the N₂/O₂ RF cleaning regime. Furthermore, since the NF₃/O₂ introduced from the RPS is mainly cleaning the chamber below the processing regions 130 and 135, the on time of the remote plasma sources 110 is minimized. This also minimizes the AlFₓ formation on the chamber sidewalls 160, due to a decrease in fluorine provided to the chamber interior. Additionally, any AlFₓ formation on chamber components falls to the bottom of the chamber, where the AlFₓ can be removed by the pump 150, rather than falling on to a substrate being processed.

With increased high RF power (an increase of about double), the multi-source plasma cleaning method as described herein demonstrates that cleaning efficiency is approximately correlated to the applied RF power, but cleaning efficiency decreases dramatically with a larger spacing.

In many fabrication processes, post-deposition cleaning is followed by a chamber seasoning process to condition the chamber surfaces. As described above, the nitrogen-oxygen based RF plasma will remove aluminum oxycarbide surface passivation of aluminum nitride and furthermore minimizes the formation of AlFₓ by recovering the aluminum nitride surface in addition to forming a polymeric C—N layer.

The presence of the polymeric C—N layer provides multiple benefits. The first benefit of the polymeric C—N layer is an increase in the coefficient of friction of the heated pedestal 145 (made of aluminum nitride (AlN)). The increased coefficient of friction reduces substrate sliding, mitigating false positive instances of arcing, in-film defect out of specification occurrences, substrate chipping and hardware damage, loss of chucking, and backside punchthrough. Previous strategies to mitigated substrate sliding demonstrated diminished substrate-center errors with standalone treatment as preventative maintenance or to recover performance that is out of specification. The approach developed using N₂/O₂ RF plasma is occurring in parallel with the cleaning and maintains quality substrate-in-center performance.

The second benefit of the C—N layer is minimization of the formation of AlFₓ due to exposure to fluorine based RPS cleaning. Since C—N is highly resistant to fluorine based etching, the AlN beneath the C—N film layer is protected from fluorine radicals. Furthermore, AlN is actively sustained from N₂/O₂ plasma during RF cleaning, the heater damage due to formation of AlFₓ is mitigated, which is demonstrated by repeatability testing showing stable film properties for more than 500 substrates. The repeatability testing showed stable deposition rates, uniformity, and film properties in specifications, as well a decrease in defects.

Utilizing the multi-source plasma cleaning method as described herein, a successful implementation of high throughput process at temperature of greater than about 400 degrees Celsius is provided. The multi-source plasma cleaning method as described herein can be applied to any other processes (e.g., oxide/nitride/doped carbon process) for chambers configured for high throughput with high RF power and RPS cleaning. The multi-source plasma cleaning method as described herein provides enhanced quality control by providing a high throughput solution.

While the foregoing is directed to implementations of the present disclosure, other and further implementations of the disclosure may be devised without departing from the basic scope thereof, and the scope thereof is determined by the claims that follow.

1. A method of cleaning a deposition chamber, comprising:
flowing a nitrogen containing gas into a processing region within the deposition chamber;
striking a plasma in the processing region utilizing a radio frequency power;
introducing a cleaning gas into a remote plasma source that is fluidly connected to the deposition chamber;
generating reactive species of the cleaning gas in the remote plasma source;
introducing the cleaning gas into the deposition chamber; and
removing deposits on interior surfaces of the deposition chamber at different etch rates.

2. The method of claim 1, wherein the nitrogen containing gas comprises nitrogen and oxygen.

3. The method of claim 2, wherein the cleaning gas comprises nitrogen and oxygen.

4. The method of claim 3, wherein the cleaning gas comprises fluorine.

5. The method of claim 1, wherein the cleaning gas comprises nitrogen trifluoride and oxygen.

6. The method of claim 1, wherein the cleaning gas is flowed into the deposition chamber simultaneously with the nitrogen containing gas.

7. The method of claim 1, wherein the cleaning gas is flowed into the deposition chamber after the nitrogen containing gas is flowed into the deposition chamber.

8. A method of cleaning a deposition chamber, comprising:
flowing a nitrogen containing gas into a processing region within the deposition chamber;
striking a plasma in the processing region utilizing a radio frequency power;
introducing a cleaning gas into a remote plasma source that is fluidly connected to the deposition chamber;
generating reactive species of the cleaning gas in the remote plasma source;
introducing the cleaning gas into the deposition chamber; and
removing deposits on interior surfaces of the deposition chamber at different temperatures.

9. The method of claim 8, wherein an upper portion of the deposition chamber is cleaned using the nitrogen containing gas.

10. The method of claim 9, wherein a lower portion of the deposition chamber is cleaned using the cleaning gas.

11. The method of claim 8, wherein the nitrogen containing gas comprises nitrogen and oxygen.

12. The method of claim 11, wherein the cleaning gas comprises nitrogen and oxygen.

13. The method of claim 12, wherein the cleaning gas comprises fluorine.

14. The method of claim 8, wherein the cleaning gas is flowed into the deposition chamber simultaneously with the nitrogen containing gas.

15. The method of claim 8, wherein the cleaning gas is flowed into the deposition chamber after the nitrogen containing gas is flowed into the deposition chamber.

16. A method of cleaning a deposition chamber, comprising:
flowing a first gas into a processing region within the deposition chamber;
striking a plasma of the first gas in the processing region utilizing a radio frequency power;
introducing a second gas into a remote plasma source that is fluidly connected to the deposition chamber;
generating reactive species of the second gas in the remote plasma source;
introducing the second gas into the deposition chamber; and
removing deposits on interior surfaces of the deposition chamber at different temperatures and etch rates.

17. The method of claim 16, wherein the first gas comprises nitrogen and oxygen.

18. The method of claim 17, wherein the second gas comprises nitrogen and oxygen.

19. The method of claim 18, wherein the second gas comprises fluorine.

20. The method of claim 16, wherein the second gas is flowed into the deposition chamber after the first gas is flowed into the deposition chamber.
